(19) United States
(12) Patent Application Publication
(10) Pub. No.: US 2024/0405174 A1
(43) Pub. Date: Dec. 5, 2024

(54) DISPLAY DEVICE

(71) Applicant: Samsung Display Co., LTD., Yongin-si (KR)

(72) Inventors: SANG YOUN HAN, Yongin-si (KR); TAEGON KIM, Yongin-si (KR); JONG-RYUK PARK, Yongin-si (KR); HOKIL OH, Yongin-si (KR)

(21) Appl. No.: 18/435,112

(22) Filed: Feb. 7, 2024

(30) Foreign Application Priority Data
Jun. 1, 2023 (KR) 10-2023-0071073

(51) Int. Cl. H01L 33/62; H01L 25/075; H01L 25/16; H01L 27/12

(52) U.S. Cl. CPC H01L 33/62; H01L 25/0753; H01L 25/167; H01L 27/1244

(57) ABSTRACT

A display device includes a substrate including a display area, and a pad area at one side of the display area, first input pads and second input pads at one side of the pad area above the substrate, signal pads in the pad area above the substrate, and under the first and second input pads in a plan view, first signal lines electrically connecting the signal pads and the first input pads in a one-to-many or many-to-many manner, second signal lines electrically connecting the signal pads and the second input pads in a one-to-one manner, and an organic insulating layer covering edges of the first signal lines so that at least a part of upper surfaces of the first signals lines is exposed.

### CROSS-REFERENCE TO RELATED APPLICATION

The present application claims priority to, and the benefit of, Korean Patent Application No. 10-2023-0071073, filed on Jun. 1, 2023, in the Korean Intellectual Property Office, the entire disclosure of which is incorporated herein by reference.

### BACKGROUND

### 1. Field

Embodiments relate to a display device that provides visual information.

### 2. Description of the Related Art

As information technology develops, the importance of display devices, which are communication media between users and information, is being highlighted. Accordingly, the use of display devices, such as a liquid crystal display device, an organic light-emitting display device, a plasma display device, and the like is increasing.

### SUMMARY

Embodiments provide a display device having improved performance against defects.

A display device according to embodiments of the present disclosure includes a substrate including a display area, and a pad area at one side of the display area, first input pads and second input pads at one side of the pad area above the substrate, signal pads in the pad area above the substrate, and under the first and second input pads in a plan view, first signal lines electrically connecting the signal pads and the first input pads in a one-to-many or many-to-many manner, second signal lines electrically connecting the signal pads and the second input pads in a one-to-one manner, and an organic insulating layer covering edges of the first signal lines so that at least a part of upper surfaces of the first signals lines is exposed.

The organic insulating layer may extend to cover edges of the second input pads and at least a part of the second signal lines.

The organic insulating layer may expose a part of the second signal lines overlapping an area adjacent to the second input pads.

The display device may further include a lighting circuit portion in the pad area above the substrate, and third signal lines connected to the lighting circuit portion, wherein the organic insulating layer extends to cover at least a part of the third signal lines, and exposes a part of the third signal lines overlapping an area adjacent to ends of the third signal lines.

At least a part of a space between corresponding ones of the first signal lines may be exposed by the organic insulating layer.

The display device may further include a dummy pad between corresponding ones of the first input pads in the pad area, wherein the organic insulating layer extends to cover at least a part of edges of the dummy pad.

The organic insulating layer may expose another part of the edges of the dummy pad.

The first signal lines and the first input pads may be grouped into groups, wherein a part of the organic insulating layer covering edges of the first signal lines in a first group among the groups is disconnected from another part of the organic insulating layer covering edges of the first signal lines in a second group among the groups that is adjacent to the first group.

The first input pads and the second input pads may include a first conductive layer, a second conductive layer above the first conductive layer, and a third conductive layer above the second conductive layer.

The first signal lines may be integral with the third conductive layer of the first input pads, wherein the second signal lines are integral with the third conductive layer of the second input pads.

The third conductive layer may have a multilayer structure including Ti/Al/Ti.

The display device may further include output pads at another side of the pad area above the substrate, and a driving integrated circuit on the first input pads, the second input pads, and the output pads, and electrically connected to the first input pads, the second input pads, and the output pads.

A display device according to embodiments of the present disclosure includes a substrate including a display area, and a pad area at one side of the display area, first input pads and second input pads at one side of the pad area above the substrate, first signal lines electrically connected to the first input pads in a one-to-many correspondence, second signal lines electrically connected to the second input pads in a one-to-one or many-to-one correspondence, and an organic insulating layer covering edges of the first signal lines so that at least a part of an upper surface of each of the first signals lines is exposed.

The organic insulating layer may extend to cover edges of each of the second input pads and at least a part of the second signal lines.

The organic insulating layer may expose a part of the second signal lines overlapping an area adjacent to the second input pads.

The display device may further include a lighting circuit portion in the pad area above the substrate, and third signal lines connected to the lighting circuit portion, wherein the organic insulating layer extends to cover at least a part of the third signal lines, and exposes a part of the third signal lines overlapping an area adjacent to ends of the third signal lines.

At least a part of a space between corresponding ones of the first signal lines may be exposed by the organic insulating layer.

The display device may further include a dummy pad between corresponding ones of the first input pads in the pad area, wherein the organic insulating layer extends to cover at least a part of edges of the dummy pad.

The organic insulating layer may expose another part of the edges of the dummy pad.

The first signal lines and the first input pads may be grouped into groups, wherein a part of the organic insulating layer covering edges of the first signal lines in a first group among the groups is disconnected from another part of the organic insulating layer covering edges of the first signal lines in a second group among the groups that is adjacent to the first group.

A display device according to one or more embodiments of present discourse may include a plurality of first input pads and a plurality of second input pads located in one side of the pad area, a plurality of first signal lines electrically connecting the first input pads in a one-to-many correspondence, a plurality of second signal lines electrically connecting the second input pads in a one-to-one or many-to-one correspondence, and an organic insulating layer covering edges of each of the first signal lines so that at least a part of an upper surface of each of the first signals lines is exposed and exposing at least a part of a space between the first signal lines. In addition, the organic insulating layer may expose a part of the second signal lines overlapping a first area adjacent to the second input pads, and may expose a part of the third signal lines overlapping a second area adjacent to the second input pads. Accordingly, a moisture permeation path through the organic insulating layer can be blocked. In this case, a lifting phenomenon of the driving integrated circuit that occurs after performing reliability evaluation on the display device in a high temperature and high humidity environment can be improved.

### BRIEF DESCRIPTION OF DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is a view illustrating a bent shape of the display device of FIG. 1.

FIG. 3 is a block diagram illustrating an external device electrically connected to the display device of FIG. 1.

FIG. 4 is a cross-sectional view illustrating a cross-section taken along the line I-I′ of FIG. 1.

FIGS. 5 and 6 are enlarged plan views of area A of FIG. 1.

FIG. 7 is a cross-sectional view illustrating a driving integrated circuit located on a plurality of pads of FIG. 6.

FIG. 8 is an enlarged plan view illustrating area B in FIG. 1.

FIG. 9 is an enlarged plan view of area C of FIG. 8.

FIG. 10 is a plan view illustrating a dummy pad and an organic insulating layer of FIG. 8.

FIG. 11 is a plan view illustrating another example of a dummy pad and an organic insulating layer of FIG. 8.

FIG. 12 is cross-sectional views taken along the lines II-II′ and III-III′ of FIG. 8.

FIG. 13 is cross-sectional views taken along the lines IV-IV′ and V-V′ of FIG. 8.

FIG. 14 is an enlarged plan view of another example of area B in FIG. 1.

FIG. 15 is an enlarged plan view of area D of FIG. 14.

FIG. 16 is a cross-sectional view illustrating another example of a cross-section taken along the line I-I′ of FIG. 1.

FIG. 17 is a block diagram illustrating an electronic device including the display device of FIG. 1.

FIG. 18 is a view illustrating the electronic device of FIG. 17 implemented as a television.

FIG. 19 is a view illustrating the electronic device of FIG. 17 implemented as a smartphone.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices such as field programmable gate arrays (FPGAs).

Further, the various components of these devices may be a process or thread, running on one or more processors, in one or more computing devices, executing computer program instructions and interacting with other system components for performing the various functionalities described herein. The computer program instructions are stored in a memory that may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

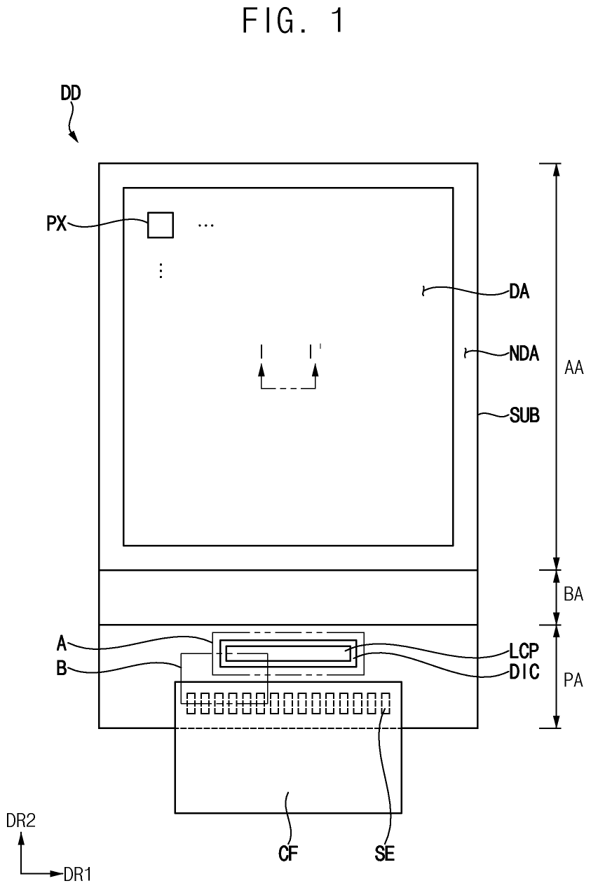

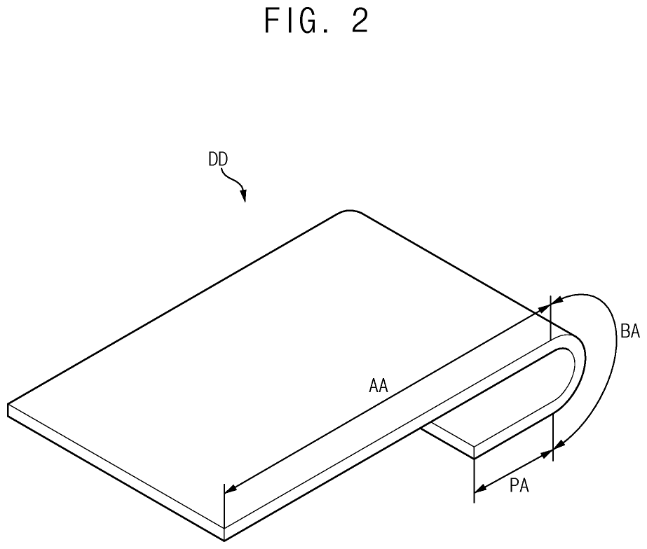

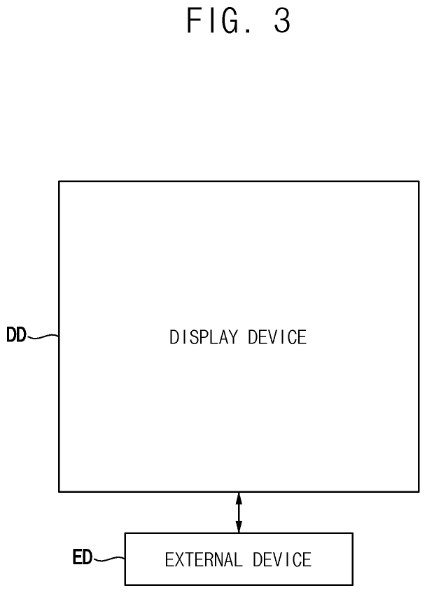

FIG. 1 is a plan view illustrating a display device according to one or more embodiments of the present disclosure. FIG. 2 is a view illustrating a bent shape of the display device of FIG. 1. FIG. 3 is a block diagram illustrating an external device electrically connected to the display device of FIG. 1.

Referring to FIGS. 1, 2, and 3, a display device DD according to one or more embodiments of the present disclosure may include a substrate SUB, a driving integrated circuit DIC, signal pads SE, and a connection film CF.

The display device DD may have a rectangular planar shape (e.g., a rectangular planar shape with rounded corners). However, embodiments of the present disclosure are not limited to this, and the display device DD may have various planar shapes.

The substrate SUB may include a display area DA and a non-display area NDA. The display area DA may be defined as an area that can display an image by generating light, or by adjusting the transmittance of light provided from an external light source. The non-display area NDA may be defined as an area that does not display images. In addition, the non-display area NDA may surround at least a part of the display area DA (e.g., in plan view). For example, the non-display area NDA may entirely surround the display area DA.

The non-display area NDA may include a bending area BA and a pad area PA. The pad area PA may be located in one side of the display area DA. For example, the pad area PA may be located spaced apart from one side of the display area DA in a direction opposite to a second direction DR2 parallel to an upper surface of the substrate SUB.

The bending area BA may be located between the display area DA and the pad area PA in a plan view. As shown in FIG. 2, the bending area BA may be bent based on a bending axis extending in a first direction DR1. In this case, the pad area PA may overlap an area AA defined as the display area DA and part of the non-display area NDA in the plan view. For example, the pad area PA may be located under the area AA (e.g., in a thickness direction). The display device DD may be provided in a shape in which the bending area BA is bent about the bending axis.

A plurality of pixels PX may be arranged in the display area DA. Each of the plurality of pixels PX may emit light. As each of the plurality of pixels PX emits light, the display area DA may display an image. For example, the plurality of pixels PX may be arranged in a matrix form along the first direction DR1 and along the second direction DR2 crossing the first direction DR1.

Lines connected to the plurality of pixels PX may be further located in the display area DA. For example, the lines may include data signal lines, gate signal lines, power lines, and the like.

A driver for driving the plurality of pixels PX may be located in the non-display area NDA. For example, the driver may include a gate driver, a light-emitting driver, a power supply voltage generator, a timing controller, and the like. The plurality of pixels PX may emit light based on signals received from the driver.

A lighting circuit portion LCP may be located in the pad area PA on the substrate SUB. The lighting circuit portion LCP may perform a lighting inspection of the pixels PX. The lighting circuit portion LCP may include semiconductor elements, such as a plurality of transistors. For example, the lighting circuit portion LCP may be located in an area where the driving integrated circuit DIC is located. However, embodiments of the present disclosure are not limited thereto.

The driving integrated circuit DIC may be located in the pad area PA on the substrate SUB. The driving integrated circuit DIC may convert a digital data signal among the driving signals into an analog data signal, and may provide the converted data signal to the plurality of pixels PX. For example, the driving integrated circuit DIC may be a data driver.

The signal pads SE may be located in the pad area PA on the substrate SUB. The signal pads SE may overlap an end of the pad area PA, and may be located under the driving integrated circuit DIC in the plan view. The signal pads SE may be arranged to be spaced apart from each other in the first direction DR1. Some of the signal pads SE may be connected to the driving integrated circuit DIC through lines, and the remainder of the signal pads SE may be connected to the plurality of pixels PX through lines. For example, each of the signal pads SE may include metal, alloy, metal nitride, conductive metal oxide, transparent conductive material, and/or the like. These can be used alone or in combination with each other.

The connection film CF may be located on the pad area PA on the substrate SUB. For example, the connection film CF may overlap a part of the pad area PA. One end of the connection film CF may be electrically connected to the signal pads SE, and the other end of the connection film CF may be electrically connected to an external device ED. That is, the driving signal, driving voltage, and the like generated from the external device ED may be provided to the driving integrated circuit DIC and to the plurality of pixels PX through the connection film CF and signal pads SE. For example, the connection film CF may include a flexible printed circuit board (FPCB), a printed circuit board (PCB), a flexible flat cable (FFC), or the like.

As shown in FIG. 3, the external device ED may be electrically connected to the display device DD. For example, the external device ED may be electrically connected to the display device DD through the connection film CF. The external device ED may generate a driving signal, a driving voltage, and the like to display an image on the display device DD.

In FIG. 1, the driving integrated circuit DIC is shown as being located in a chip-on-plastic (COP) method or a chip-on-glass (COG) method, but embodiments of the present disclosure are not limited thereto. For example, the driving integrated circuit DIC may be located in a chip-on-film (COF) method.

In this specification, a plane (e.g., plan view) may be defined as the first direction DR1 and the second direction DR2 crossing the first direction DR1. For example, the first direction DR1 may be substantially perpendicular to the second direction DR2.

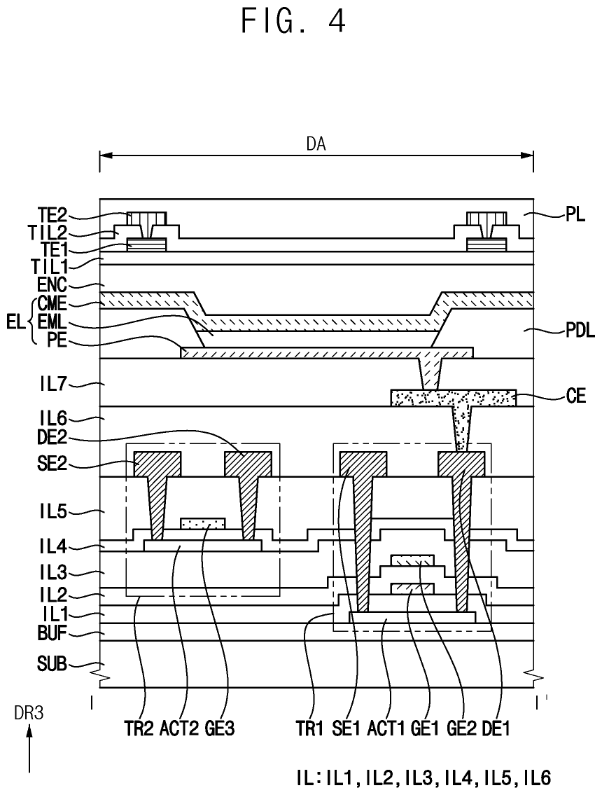

FIG. 4 is a cross-sectional view illustrating a cross-section taken along the line I-I′ of FIG. 1. For example, FIG. 4 is a cross-sectional view illustrating a part of the display area DA of FIG. 1.

Referring to FIG. 4, the display device DD according to one or more

embodiments of the present disclosure may include the substrate SUB, a buffer layer BUF, first and second transistors TR1 and TR2, first, second, third, fourth, fifth, sixth, and seventh insulating layers IL1, IL2, IL3, IL4, IL5, IL6, and IL7, a connection electrode CE, a pixel-defining layer PDL, a light-emitting element EL, an encapsulation layer ENC, and a touch-sensing layer.

Here, the first transistor TR1 may include a first active pattern ACT1, a first gate electrode GE1, a second gate electrode GE2, a first source electrode SE1, and a first drain electrode DE1. The second transistor TR2 may include a second active pattern ACT2, a third gate electrode GE3, a second source electrode SE2, and a second drain electrode DE2. The light-emitting element EL may include a pixel electrode PE, a light-emitting layer EML, and a common electrode CME.

The substrate SUB may include a transparent material or an opaque material. The substrate SUB may be made of a transparent resin substrate. Examples of the transparent resin substrate include a polyimide substrate. In this case, the polyimide substrate may include a first organic layer, a first barrier layer, a second organic layer, and the like. Alternatively, the substrate SUB may include a quartz substrate, a synthetic quartz substrate, a calcium fluoride substrate, a fluorine-doped quartz substrate, a soda-lime glass substrate, non-alkali glass substrate, and/or the like. These can be used alone or in combination with each other.

The buffer layer BUF may be located on the substrate SUB. The buffer layer BUF may reduce or prevent metal atoms or impurities from diffusing from the substrate SUB to the first and second transistors TR1 and TR2. In addition, the buffer layer BUF can improve the flatness of the surface of the substrate SUB when the surface of the substrate SUB is not uniform. For example, the buffer layer BUF may include an inorganic material, such as silicon oxide (SiOₓ), silicon nitride (SiNₓ), silicon oxynitride (SiOₓN_{y}), and/or the like. These can be used alone or in combination.

The first active pattern ACT1 may be located on the buffer layer BUF. In one or more embodiments, the first active pattern ACT1 may include an inorganic semiconductor, such as amorphous silicon or polycrystalline silicon. For example, the first active pattern ACT1 may have a first source region, a first drain region, and a first channel region located between the first source region and the first drain region.

The first insulating layer IL1 may be located on the buffer layer BUF. The first insulating layer IL1 may cover the first active pattern ACT1 and may be located along the profile of the first active pattern ACT1 with a substantially uniform thickness. Alternatively, the first insulating layer IL1 may sufficiently cover the first active pattern ACT1, and may have a substantially flat upper surface without creating a step around the first active pattern ACT1. For example, the first insulating layer IL1 may include an inorganic material, such as silicon oxide (SiOₓ), silicon nitride (SiNₓ), silicon carbide (SiCₓ), silicon oxynitride (SiOₓN_{y}), silicon oxycarbide (SiOₓC_{y}), and/or the like. These can be used alone or in combination with each other. The first insulating layer IL1 may be defined as a first gate-insulating layer.

The first gate electrode GE1 may be located on the first insulating layer IL1. The first gate electrode GE1 may overlap the first channel region of the first active pattern ACT1. The first gate electrode GE1 may include metal, alloy, metal nitride, conductive metal oxide, transparent conductive material, and/or the like. Examples of the metal may include silver (Ag), molybdenum (Mo), aluminum (AI), tungsten (W), copper (Cu), nickel (Ni), chromium (Cr), titanium (Ti), and tantalum (Ta), platinum (Pt), scandium (Sc), and/or the like. Examples of the conductive metal oxide include indium tin oxide and indium zinc oxide. In addition, examples of the metal nitride may include aluminum nitride (AlNₓ), tungsten nitride (WNₓ), chromium nitride (CrNₓ), and/or the like. These can be used individually or in combination with each other.

The second insulating layer IL2 may be located on the first insulating layer IL1. The second insulating layer IL2 covers the first gate electrode GE1, and may have a substantially uniform thickness along the profile of the first gate electrode GE1. Alternatively, the second insulating layer IL2 may sufficiently cover the first gate electrode GE1, and may have a substantially flat upper surface without creating a step around the first gate electrode GE1. For example, the second insulating layer IL2 may include an inorganic material, such as silicon oxide, silicon nitride, silicon oxynitride, and/or the like. These can be used alone or in combination with each other. The second insulating layer IL2 may be defined as a second gate-insulating layer.

The second gate electrode GE2 may be located on the second insulating layer IL2. The second gate electrode GE2 may overlap the first gate electrode GE1. For example, the second gate electrode GE2 may include metal, alloy, metal nitride, conductive metal oxide, transparent conductive material, and/or the like. These can be used alone or in combination with each other.

The third insulating layer IL3 may be located on the second insulating layer IL2 and the second gate electrode GE2. The third insulating layer IL3 may cover the second gate electrode GE2, and may have a substantially uniform thickness along the profile of the second gate electrode GE2. Alternatively, the third insulating layer IL3 may sufficiently cover the second gate electrode GE2, and may have a substantially flat upper surface without creating a step around the second gate electrode GE2. For example, the third insulating layer IL3 may include an inorganic material, such as silicon oxide, silicon nitride, silicon oxynitride, and/or the like. These can be used alone or in combination with each other. The third insulating layer IL3 may be defined as the first interlayer insulating layer.

The second active pattern ACT2 may be located on the third insulating layer IL3. In one or more embodiments, the second active pattern ACT2 may include a metal oxide semiconductor. For example, the second active pattern ACT2 may have a second source region, a second drain region, and a second channel region located between the second source region and the second drain region.

The metal oxide semiconductor may include a binary compound (ABₓ), a ternary compound (ABₓC_{y}), a four-component compound (ABₓC_{y}D_{z}) containing indium (In), zinc (Zn), gallium (Ga), tin (Sn), titanium (Ti), aluminum (AI), hafnium (Hf), zirconium (Zr), magnesium (Mg), and/or the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and/or the like. These can be used alone or in combination with each other.

The fourth insulating layer IL4 may be located on the third insulating layer IL3. The fourth insulating layer IL4 may cover the second active pattern ACT2, and may be located along the profile of the second active pattern ACT2 with a substantially uniform thickness. Alternatively, the fourth insulating layer IL4 may sufficiently cover the second active pattern ACT2, and may have a substantially flat upper surface without creating a step around the second active pattern ACT2. For example, the fourth insulating layer IL4 may include an inorganic material, such as silicon oxide, silicon nitride, silicon oxynitride, and/or the like. These can be used alone or in combination with each other. The fourth insulating layer IL4 may be defined as a third gate-insulating layer.

The third gate electrode GE3 may be located on the fourth insulating layer IL4. The third gate electrode GE3 may overlap the second channel region of the second active pattern ACT2. For example, the third gate electrode GE3 may include metal, alloy, metal nitride, conductive metal oxide, transparent conductive material, and/or the like. These can be used alone or in combination with each other.

The fifth insulating layer IL5 may be located on the fourth insulating layer IL4. The fifth insulating layer IL5 may sufficiently cover the third gate electrode GE3, and may have a substantially flat upper surface without creating a step around the third gate electrode GE3. Alternatively, the fifth insulating layer IL5 may cover the third gate electrode GE3, and may have a substantially uniform thickness along the profile of the third gate electrode GE3. For example, the fifth insulating layer IL5 may include an inorganic material, such as silicon oxide, silicon nitride, silicon oxynitride, and/or the like. These can be used alone or in combination with each other. The fifth insulating layer IL5 may be defined as a second interlayer insulating layer.

The first source electrode SE1 and the first drain electrode DE1 may be located in the display area DA on the fifth insulating layer IL5. The first source electrode SE1 may be connected to the first source region of the first active electrode through a contact hole penetrating a first part of an inorganic insulating layer (e.g., the first, second, third, fourth, and fifth insulating layers IL1, IL2, IL3, IL4, and IL5). The first drain electrode DE1 may be connected to the first drain region of the first active pattern ACT1 through a contact hole penetrating a second part of the inorganic insulating layer. For example, each of the first source electrode SE1 and the first drain electrode DE1 may include a metal, an alloy, a metal nitride, a conductive metal oxide, a transparent conductive material, and/or the like. These can be used alone or in combination with each other. In one or more embodiments, each of the first source electrode SE1 and the first drain electrode DE1 may have a multilayer structure including Ti/Al/Ti.

The second source electrode SE2 and a second drain electrode DE2 may be located on the fifth insulating layer IL5. The second source electrode SE2 may be connected to the second source region of the second active pattern ACT2 through a contact hole penetrating a first part of the fourth and fifth insulating layers IL4 and IL5. The second drain electrode DE2 may be connected to the second drain region of the second active pattern ACT2 through a contact hole penetrating a second part of the fourth and fifth insulating layers IL4 and IL5. The second source electrode SE2 and the second drain electrode DE2 may include the same material as the first source electrode SE1 and the first drain electrode DE1, and may be located in the same layer as the first source electrode SE1 and the first drain electrode DE1.

Accordingly, the first transistor TR1 including the first active pattern ACT1, the first gate electrode GE1, the second gate electrode GE2, the first source electrode SE1, and the first drain electrode DE1 may be located in the display area DA, and the second transistor TR2 including the second active pattern ACT2, the third gate electrode GE3, the second source electrode SE2, and the second drain electrode DE2 may be located in the display area DA. Here, the first transistor TR1 may be defined as a driving transistor, and the second transistor TR2 may be defined as a switching transistor.

The sixth insulating layer IL6 may be located on the fifth insulating layer IL5. The sixth insulating layer IL6 may sufficiently cover the first source electrode SE1, the first drain electrode DE1, the second source electrode SE2, and the second drain electrode DE2. To this end, the sixth insulating layer IL6 may have a substantially flat upper surface. The sixth insulating layer IL6 may include an organic material. For example, the sixth insulating layer IL6 may include an organic material, such as polyimide resin, polyamide resin, siloxane resin, epoxy resin, and/or the like. These can be used alone or in combination with each other. The sixth insulating layer IL6 may be defined as a first organic insulating layer.

The first, second, third, fourth, fifth, and sixth insulating layers IL1, IL2, IL3, IL4, IL5, and IL6 may form one insulating structure IL.

The connection electrode CE may be located on the sixth insulating layer IL6. The connection electrode CE may be connected to the first drain electrode DE1 (or to the first source electrode SE1) through a contact hole penetrating the sixth insulating layer IL6. Accordingly, the connection electrode CE may electrically connect the first transistor TR1 and the light-emitting element EL. For example, the connection electrode CE may include metal, alloy, metal nitride, conductive metal oxide, transparent conductive material, and/or the like. These can be used alone or in combination with each other. In one or more embodiments, the connection electrode CE may have a multilayer structure including Ti/Al/Ti.

The seventh insulating layer IL7 may be located on the sixth insulating layer IL6. The seventh insulating layer IL7 may sufficiently cover the connection electrode CE. To this end, the seventh insulating layer IL7 may have a substantially flat upper surface. The seventh insulating layer IL7 may include an organic material. For example, the seventh insulating layer IL7 may include an organic material, such as polyimide resin, polyamide resin, siloxane resin, epoxy resin, and/or the like. These can be used alone or in combination with each other. The seventh insulating layer IL7 may be defined as a second organic insulating layer.

The pixel electrode PE may be located on the seventh insulating layer IL7. The pixel electrode PE may be connected to the connection electrode CE through a contact hole penetrating the seventh insulating layer IL7. For example, the pixel electrode PE may include metal, alloy, metal nitride, conductive metal oxide, transparent conductive material, and/or the like. These can be used alone or in combination with each other. For example, the pixel electrode can act as an anode.

The pixel-defining layer PDL may be located on the seventh insulating layer IL7. The pixel-defining layer PDL may cover the edge of the pixel electrode PE. For example, the pixel-defining layer PDL may include an inorganic material and/or an organic material. In one or more embodiments, the pixel-defining layer PDL may include an organic material, such as epoxy resin, siloxane resin, and/or the like. These can be used alone or in combination with each other. In one or more other embodiments, the pixel-defining layer PDL may include an inorganic material and/or an organic material containing a light blocking material, such as black pigment, black dye, and/or the like.

The light-emitting layer EML may be located on the pixel electrode PE. The light-emitting layer EML may include an organic material that emits light of a preset color. For example, the light-emitting layer EML may include an organic material that emits at least one of red light, green light, or blue light.

The common electrode CME may be located on the pixel-defining layer PDL and the emitting layer EML. For example, the common electrode CME may include metal, alloy, metal nitride, conductive metal oxide, transparent conductive material, and/or the like. These can be used alone or in combination with each other. For example, the common electrode CME may act as a cathode.

Accordingly, the light-emitting element EL including the pixel electrode PE, the light-emitting layer EML, and the common electrode CME may be located in the display area DA. The light-emitting element EL may be electrically connected to the first transistor TR1.

The encapsulation layer ENC may be located on the common electrode CME. The encapsulation layer ENC can reduce or prevent impurities, moisture, and the like from penetrating into the light-emitting element EL from the outside. The encapsulation layer ENC may include at least one inorganic layer and at least one organic layer. For example, the inorganic layer may include silicon oxide, silicon nitride, silicon oxynitride, and/or the like. These can be used alone or in combination with each other. The organic layer may include a cured polymer, such as polyacrylate.

The touch-sensing layer may be located on the encapsulation layer ENC. The touch-sensing layer may include a first touch insulating layer TIL1, a first touch insulating layer TIL2, first touch electrodes TE1, second touch electrodes TE2, and a protective layer PL.

The first touch insulating layer TIL1 may be located on the encapsulation layer ENC. The first touch insulating layer TIL1 may include an inorganic material. For example, the first touch insulating layer TIL1 may include silicon oxide, silicon nitride, silicon oxynitride, and/or the like. These can be used alone or in combination with each other.

The first touch electrodes TE1 may be located on the first touch insulating layer TIL1. For example, each of the first touch electrodes TE1 may include metal, alloy, metal nitride, conductive metal oxide, transparent conductive material, and/or the like. These can be used alone or in combination with each other.

The second touch insulating layer TIL2 may be located on the first touch insulating layer TIL1. The second touch insulating layer TIL2 may cover the first touch electrodes TE1. The second touch insulating layer TIL2 may include an inorganic material. For example, the second touch insulating layer TIL2 may include silicon oxide, silicon nitride, silicon oxynitride, and/or the like. These can be used alone or in combination with each other.

The second touch electrodes TE2 may be located on the second touch insulating layer TIL2. The second touch electrodes TE2 may be connected to the first touch electrodes TE1 through a contact hole penetrating the second touch insulating layer TIL2. The first touch electrodes TE1 and the second touch electrodes TE2 may detect an external touch and transmit the external touch to a touch driver. For example, each of the second touch electrodes TE2 may include metal, alloy, metal nitride, conductive metal oxide, transparent conductive material, and/or the like. These can be used alone or in combination with each other.

The protective layer PL may be located on the second touch insulating layer TIL2. The protective layer PL may cover the second touch electrodes TE2. The protective layer PL may protect the first and second touch electrodes TE1 and TE2 from external shock. The protective layer PL may include an organic material. For example, the protective layer PL may include an organic material, such as polyacrylic resin, polyimide resin, acrylic resin, and/or the like. These can be used alone or in combination with each other.

However, although FIG. 4 shows the touch-sensing layer being located directly on the encapsulation layer ENC, embodiments of the present invention are not limited thereto. For example, the touch-sensing layer may be located on the encapsulation layer ENC in the form of a panel including a separate base layer corresponding to a substrate.

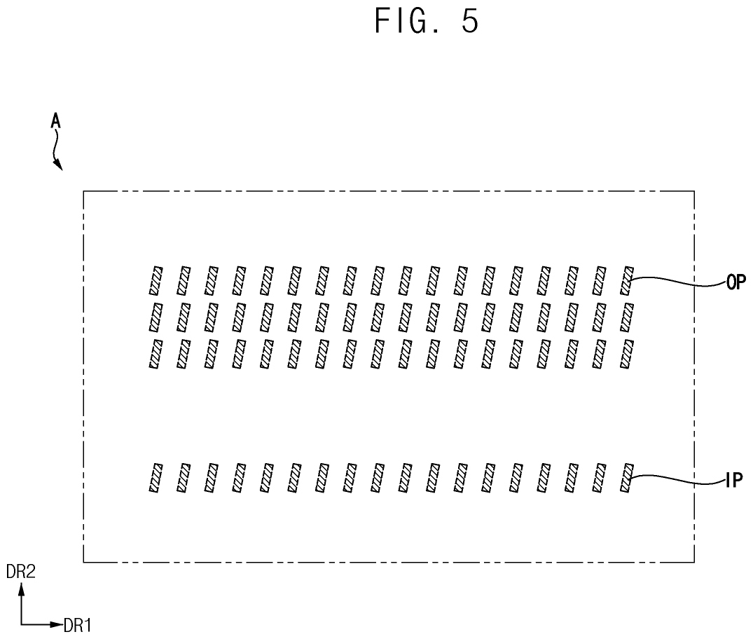

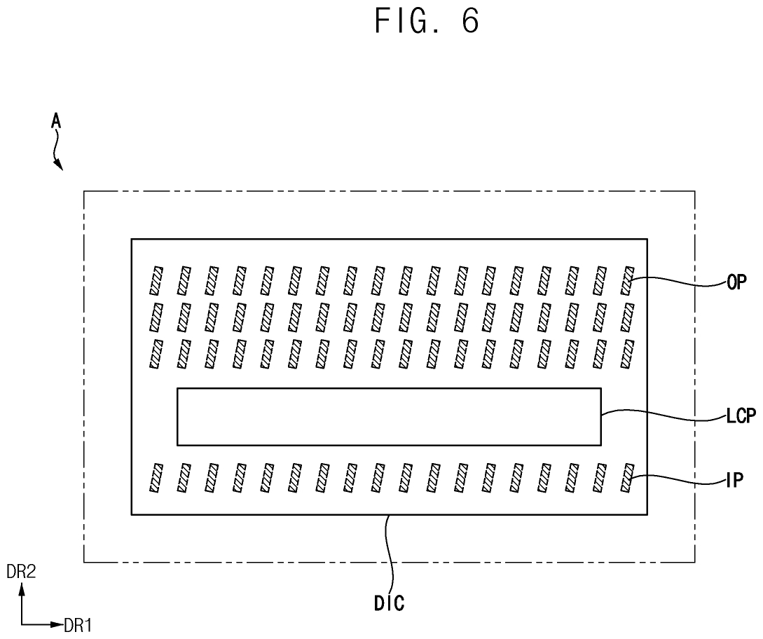

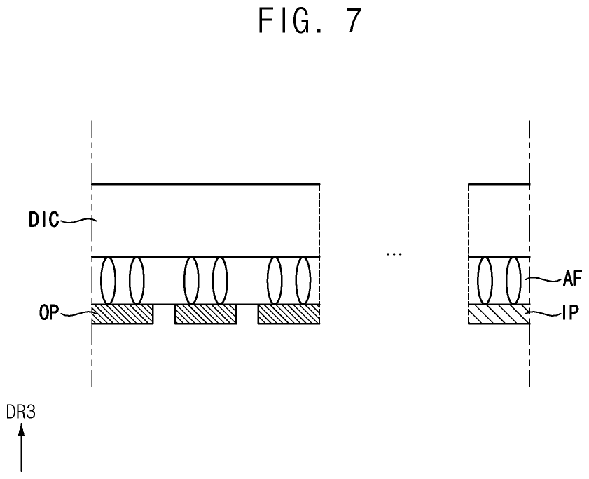

FIGS. 5 and 6 are enlarged plan views of area A of FIG. 1. FIG. 7 is a cross-sectional view illustrating a driving integrated circuit located on a plurality of pads of FIG. 6.

Referring to FIGS. 1, 5, 6, and 7, a plurality of pads may be located in the pad area PA on the substrate SUB. The plurality of pads may be repeatedly located along the first direction DR1 and the second direction DR2. The plurality of pads may include a plurality of input pads IP and a plurality of output pads OP.

The plurality of input pads IP may be located on one side of the pad area PA. The plurality of input pads IP may be located in a single line along the first direction DR1, and may be spaced apart from each other. However, embodiments of the present disclosure are not limited to this, and the plurality of input pads IP may be spaced apart from each other and may be arranged in two or more lines.

The plurality of output pads OP may be located on the other side of the pad area PA. The plurality of output pads OP may be located in three lines along the first direction DR1, and may be spaced apart from each other. However, embodiments of the present disclosure are not limited to this, and the plurality of output pads OP may be spaced apart from each other and arranged in one line, in two lines, or in four lines or more.

As described above, the lighting circuit portion LCP may be located in an area where the driving integrated circuit DIC is located. For example, the lighting circuit portion LCP may be located between the plurality of input pads IP and the plurality of output pads OP in the plan view.

The driving integrated circuit DIC may be located on the plurality of input pads IP and the plurality of output pads OP. The driving integrated circuit DIC may be electrically connected to a plurality of input pads IP and a plurality of output pads OP through a conductive film AF. For example, the conductive film AF may be an anisotropic conductive film. The driving integrated circuit DIC may output an output signal generated based on an input signal received by the plurality of input pads IP through the plurality of output pads OP.

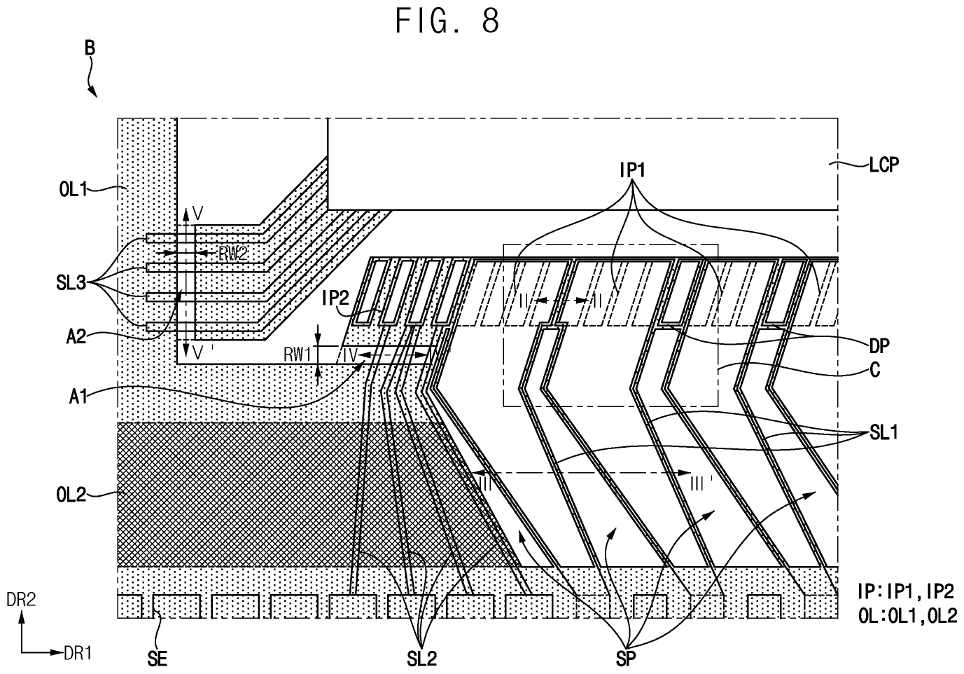

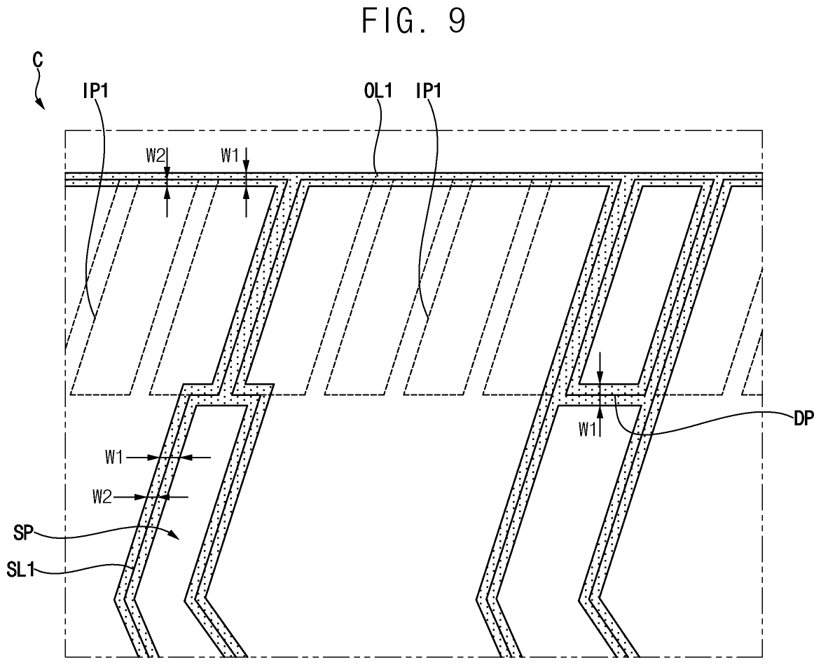

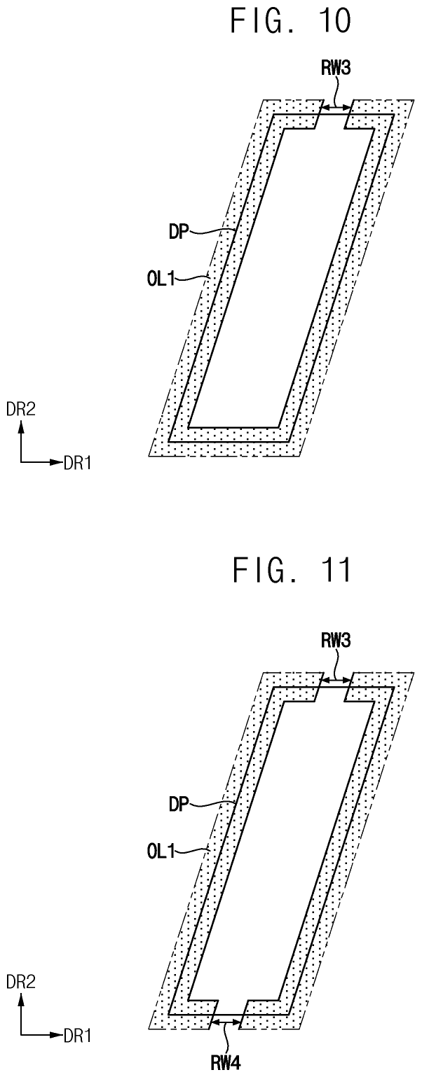

FIG. 8 is an enlarged plan view illustrating area B in FIG. 1. FIG. 9 is an enlarged plan view of area C of FIG. 8. FIG. 10 is a plan view illustrating a dummy pad and an organic insulating layer of FIG. 8. FIG. 11 is a plan view illustrating another example of a dummy pad and an organic insulating layer of FIG. 8.

Referring to FIGS. 1, 8, and 9, the display device DD according to one or more embodiments of the present disclosure may further include a plurality of first signal lines SL1, a plurality of second signal lines SL2, and a plurality of third signal lines SL3 located in the pad area PA on the substrate SUB.

The input pads IP may include a plurality of first input pads IP1 and a plurality of second input pads IP2. For example, the second input pads IP2 may be to the left and/or to the right of the first input pads IP1 in the plan view. However, embodiments of the present disclosure are not limited thereto.

The first signal lines SL1 may electrically connect the signal pads SE and the first input pads IP1. In one or more embodiments, the first signal lines SL1 may electrically connect the signal pads SE and the first input pads IP1 in a one-to-many or many-to-many manner. In addition, the first signal lines SL1 may be electrically connected to the first input pads IP1 in a one-to-many correspondence. For example, one first signal line SL1 may electrically connect one or more signal pads SE and the plurality of first input pads IP1.

The second signal lines SL2 may electrically connect the signal pads SE and the second input pads IP2. In one or more embodiments, the second signal lines SL2 may electrically connect the signal pads SE and the second input pads IP2 in a one-to-one manner. In addition, the second signal wires SL2 may be electrically connected to the second input pads IP2 in a one-to-one or many-to-one correspondence. For example, one second signal line SL2 may electrically connect one signal pad SE and one second input pad IP2.

The third signal lines SL3 may be electrically connected to the lighting circuit portion LCP. For example, the third signal lines SL3 may each be electrically connected to pads of the lighting circuit part LCP. Each of the third signal lines SL3 may extend from the lighting circuit portion LCP in a direction opposite to the first direction DR1.

For example, a lighting gate signal applied to a gate electrode of a transistor included in the lighting circuit portion LCP may be provided to a part of the third signal lines SL3. In addition, a lighting emission voltage applied to a source electrode of the transistor included in the lighting circuit portion LCP may be provided to another part of the third signal lines SL3. That is, when the lighting gate signal is applied to the gate electrode through the part of the third signal lines SL3, the lighting emission voltage may be applied to the pixel PX through another part of the third signal lines SL3 and the source electrode and drain electrode transistor, and the pixels PX may emit light. Through this process, a lighting inspection of the pixels PX may be performed.

In an area adjacent to the second signal lines SL2 of the pad area PA (e.g., an area located to the left of the second signal lines SL2), signal lines electrically connected to each of the signal pads SE may be further arranged. The signal lines may provide a driving control signal and the like to the driver through the signal pads SE.

The organic insulating layer OL may be located in the pad area PA on the substrate SUB. The organic insulating layer OL may correspond to the seventh insulating layer IL7 of FIG. 4. That is, the organic insulating layer OL may be a part of the seventh insulating layer IL7 of FIG. 4 extending as part of the pad area PA.

The organic insulating layer OL may include a first organic insulating layer OL1 and a second organic insulating layer OL2. The first organic insulating layer OL1 and the second organic insulating layer OL2 may be integrated. That is, the first organic insulating layer OL1 and the second organic insulating layer OL2 may be formed through the same mask process. In one or more embodiments, after a preliminary organic insulating layer is formed, the first organic insulating layer OL1 and the second organic insulating layer OL2 may be formed by exposing and developing the preliminary organic insulating layer using a halftone mask. A thickness of the second organic insulating layer OL2 may be thicker than a thickness of the first organic insulating layer OL1.

The organic insulating layer OL may cover the signal pads SE. For example, the first organic insulating layer OL1 of the organic insulating layer OL may cover the signal pads SE.

In one or more embodiments, the first organic insulating layer OL1 may cover the edges of each of the first signal lines SL1 so that at least a part of the upper surface of each of the first signal lines SL1 is exposed. That is, the first organic insulating layer OL1 may not entirely cover the first signal lines SL1.

In one or more embodiments, the first organic insulating layer OL1 may expose at least a part of a space SP between the first signal lines SL1. That is, the first organic insulating layer OL1 may not entirely cover the space SP between the first signal lines SL1.

The organic insulating layer OL may extend to cover the edges of each of the second input pads IP2 and at least a part of the second signal lines SL2. For example, the first organic insulating layer OL1 may cover a part of the second signal lines SL2, and the second organic insulating layer OL2 may cover a part of the second signal lines SL2, without exposing the part of the second signal lines SL2. In one or more embodiments, the first organic insulating layer OL1 may expose a part of the second signal lines SL2 overlapping the first area A1 adjacent to the second input pads IP2. That is, the first organic insulating layer OL1 may be removed from the first area A1.

For example, a width RW1 of the first area A1 may be about 5 micrometers to about 20 micrometers. For example, the width RW1 of the first area A1 may be about 10 micrometers. If the width RW1 of the first area A1 is less than about 5 micrometers, it may not be easy to block the moisture permeable path. If the width RW1 of the first area A1 exceeds about 20 micrometers, damage to the second signal lines SL2 may occur.

The organic insulating layer OL may extend to cover at least a part of the third signal lines SL3. For example, the first organic insulating layer OL1 may extend from the second signal lines SL2 to cover at least a part of the third signal lines SL3. In one or more embodiments, the first organic insulating layer OL1 may be divided into a first part extending from the second signal lines SL2 to cover at least a part of the third signal lines SL3, and a second part covering the remaining part of the third signal lines SL3 (e.g., the second part may be separated from the first part in plan view). The first organic insulating layer OL1 may expose a part of the third signal lines SL3 overlapping the second area A2 adjacent to an end of each of the third signal lines SL3. For example, the second area A2 may face the input pads IP in the first direction DR1 (or in the direction opposite to the first direction DR1), and the end part of each of the third signal lines SL3 may be a part that is not adjacent to the lighting circuit portion LCP. That is, the first organic insulating layer OL1 may be removed from the second area A2.

For example, a width RW2 of the second area A2 may be about 5 micrometers to about 20 micrometers. For example, the width RW2 of the second area A2 may be about 10 micrometers. If the width RW2 of the second area A2 is less than about 5 micrometers, it may not be easy to block the moisture permeable path through the organic insulating layer OL. If the width RW2 of the second area A2 exceeds about 20 micrometers, damage to the third signal lines SL3 may occur.

For example, in a part where the first organic insulating layer OL1 covers the edges of the first signal line SL1, a first width W1 of the first organic insulating layer OL1 may be about 6.7 micrometers. In addition, in a part where the first organic insulating layer OL1 covers the edges of the first signal line SL1, a second width W2 between an edge of the first signal line SL1 and an inner edge of the first organic insulating layer OL1 may be greater than about 0 micrometers, and less than or equal to about 5 micrometers. For example, the second width W2 between the edge of the first signal line SL1 and the inner edge of the first organic insulating layer OL1 may be about 3.5 micrometers. If the second width W2 is close to 0 micrometer, a short circuit may occur. If the second width W2 is greater than about 5 micrometers, it may not be easy to block the moisture permeation path through the organic insulating layer OL (see FIG. 9).

The display device DD may further include a dummy pad DP located in the pad area PA on the substrate SUB. The dummy pad DP may be located between the first input pads IP1 in the plan view. The dummy pad DP may not be electrically connected to the first signal lines SL1. Accordingly, the dummy pad DP may not be electrically connected to the signal pads SE.

The first organic insulating layer OL1 may extend to cover at least a part of the edges of the dummy pad DP. In this case, the first organic insulating layer OL1 may expose at least a part of the upper surface of the dummy pad DP. In one or more embodiments, the first organic insulating layer OL1 may expose a part of an edge of the dummy pad DP.

As shown in FIG. 10, the first organic insulating layer OL1 may expose a part of the upper end of the dummy pad DP. For example, a width RW3 of the part of the dummy pad DP exposed by the first organic insulating layer OL1 may be about 6.5 micrometers.

As shown in FIG. 11, the first organic insulating layer OL1 may expose a part of each of the upper and the lower end of the dummy pad DP. For example, the width RW3 of the part of the upper end of the dummy pad DP exposed by the first organic insulating layer OL1 may be about 6.5 micrometers. Likewise, a width RW4 of the part of the lower end of the dummy pad DP exposed by the first organic insulating layer OL1 may be about 6.5 micrometers. In this case, a high voltage (e.g., about 8V or more) may be applied to the first signal lines SL1 located with the dummy pad DP of FIG. 11 interposed therebetween.

In one or more embodiments, a first part of the first organic insulating layer OL1 covering the edges of one first signal line may be connected to a second part covering the edges of a first signal line adjacent to the one first signal line. Here, the first and second parts may cover the edges of a conductive layer located at the top of the first input pad IP1 and the edge of the dummy pad DP.

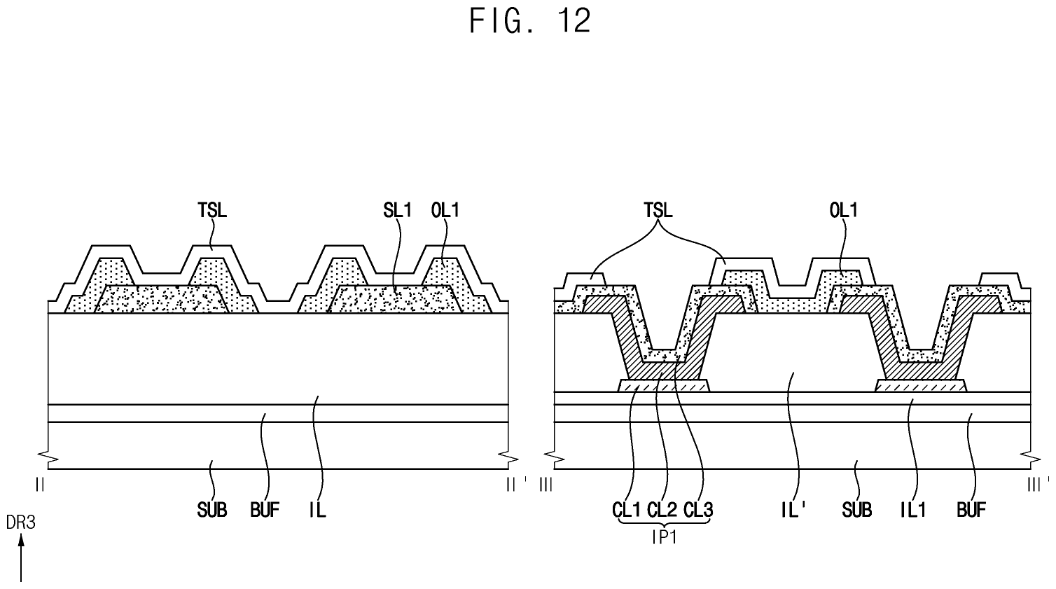

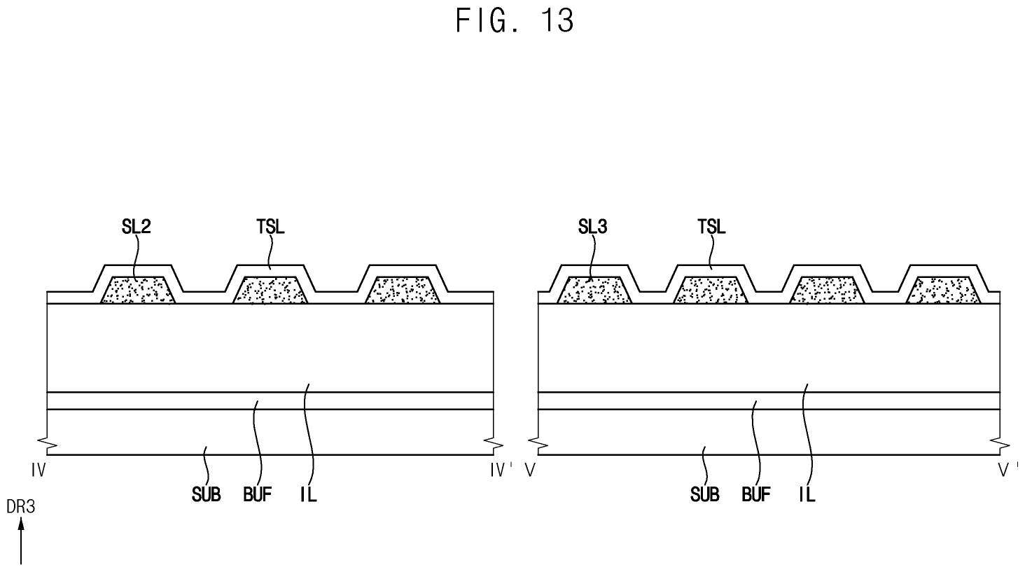

FIG. 12 is cross-sectional views taken along the lines II-II′ and III-III′ of FIG. 8. FIG. 13 is cross-sectional views taken along the lines IV-IV′ and V-V′ of FIG. 8.

Referring to FIGS. 8 and 12, a touch insulating layer TSL may be located on the insulating structure IL. The touch insulating layer TSL may cover the first signal lines SL1 and the first organic insulating layer OL1. In addition, at least a part of each of the first input pads IP1 may be exposed. The touch insulating layer TSL may include the first touch insulating layer TIL1 and the second touch insulating layer TIL2 of FIG. 4.

Each of the first input pads IP1 may have a multilayer structure. In one or more embodiments, each of the first input pads IP1 may include a first conductive layer CL1, a second conductive layer CL2 located on the first conductive layer CL1, and a third conductive layer CL3 located on the second conductive layer CL2. For example, the first conductive layer CL1 may be located on the first insulating layer IL1, the second conductive layer CL2 may contact the first conductive layer CL1 through an opening penetrating the insulating structure IL′ and exposing a part of the first conductive layer CL1, and the third conductive layer CL3 may contact the second conductive layer CL2. Here, the insulating structure IL′ may be the remainder of the insulating structure IL of FIG. 4 excluding the first insulating layer IL1. Likewise, the cross-sectional structure of each of the second input pads IP2 and the dummy pad DP may be substantially the same as the cross-sectional structure of each of the first input pads IP1. That is, each of the second input pads IP2 and the dummy pad DP may include three conductive layers.

The first conductive layer CL1 may include the same material as the first gate electrode GE1 of FIG. 4, and may be formed through the same process as the first gate electrode GE1 of FIG. 4. The second conductive layer CL2 may include the same material as, and may be formed through the same process as, the first source electrode SE1, the first drain electrode DE1, the second source electrode SE2, and the second drain electrode DE2 of FIG. 4. The third conductive layer CL3 may include the same material as the connection electrode CE of FIG. 4, and may be formed through the same process as the connection electrode CE of FIG. 4.

In one or more embodiments, the third conductive layer CL3 of each of the first input pads IP1 may be integrated with the first signal line SL1. That is, a part of the first signal line SL1 may form the third conductive layer CL3 of the first input pad IP1. Likewise, a conductive layer located at the top of each of the second input pads IP2 may be integrated with the second signal line SL2.

In one or more embodiments, the third conductive layer CL3 may have a multilayer structure including Ti/Al/Ti. That is, the third conductive layer CL3 may include a first sub-layer including Ti, a second sub-layer including Al, and a third sub-layer including Ti. In this case, each of the first and third sub-layers may protrude from the second sub-layer. Accordingly, the first and third sub-layers may form a tip.

As described above, the first organic insulating layer OL1 may cover the edges of each of the first signal lines SL1. In addition, the first organic insulating layer OL1 may cover the edges of the third conductive layer CL3 of each of the first input pads IP1. Accordingly, reduction or prevention of a short defect in the first and third sub-layers due to tip formation can be improved.

Referring further to FIG. 13, the touch insulating layer TSL may cover the second signal lines SL2 and the third signal lines SL3. That is, in the first area A1 and the second area A2, the second signal lines SL2 and the third signal lines SL3 may be not covered by the organic insulating layer OL, and instead may be covered by the touch insulating layer TSL.

Referring again to FIGS. 1, 2, 3, 4, 5, 6, 7, 8, 9, 10, 11, 12, and 13, the display device DD according to one or more embodiments of the present disclosure may include the plurality of first input pads IP1 and the plurality of second input pads IP2 located in one side of the pad area PA, the plurality of first signal lines SL1 electrically connecting the first input pads IP1 in a one-to-many correspondence, the plurality of second signal lines SL2 electrically connecting the second input pads IP2 in a one-to-one or many-to-one correspondence, and the organic insulating layer OL covering edges of each of the first signal lines SL1 so that at least a part of an upper surface of each of the first signals lines SL1 is exposed, and exposing at least a part of the space SP between the first signal lines SL1. In addition, the organic insulating layer OL may expose a part of the second signal lines SL2 overlapping the first area A1 adjacent to the second input pads IP2, and may expose a part of the third signal lines SL3 overlapping the second area A2 adjacent to the second input pads IP2. Accordingly, a moisture permeation path through the organic insulating layer OL can be blocked. In this case, a lifting phenomenon of the driving integrated circuit DIC that occurs after performing reliability evaluation on the display device DD in a high temperature and high humidity environment can be improved.

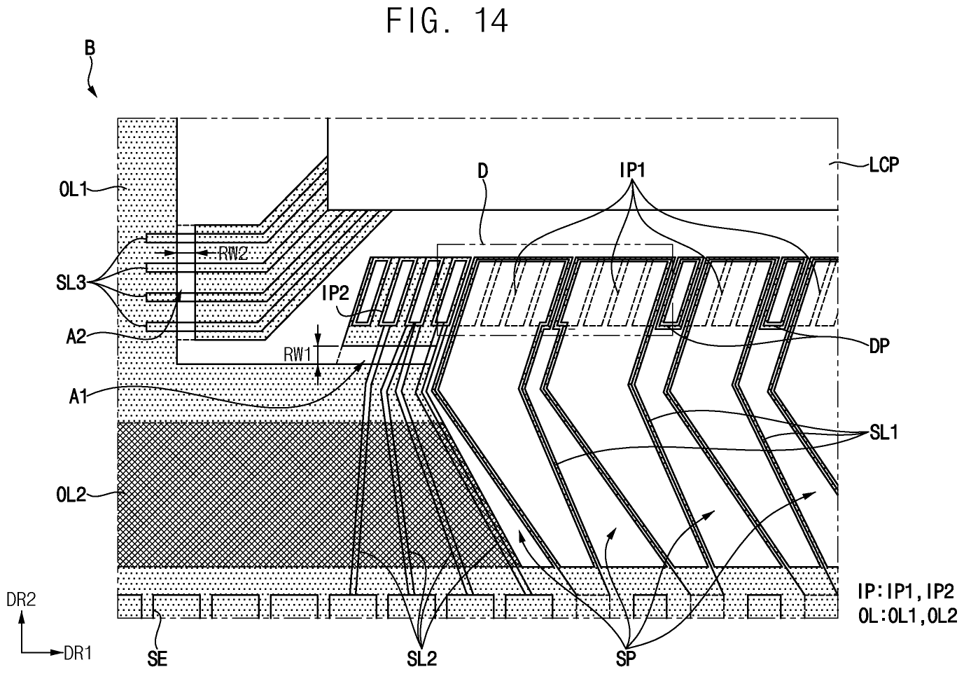

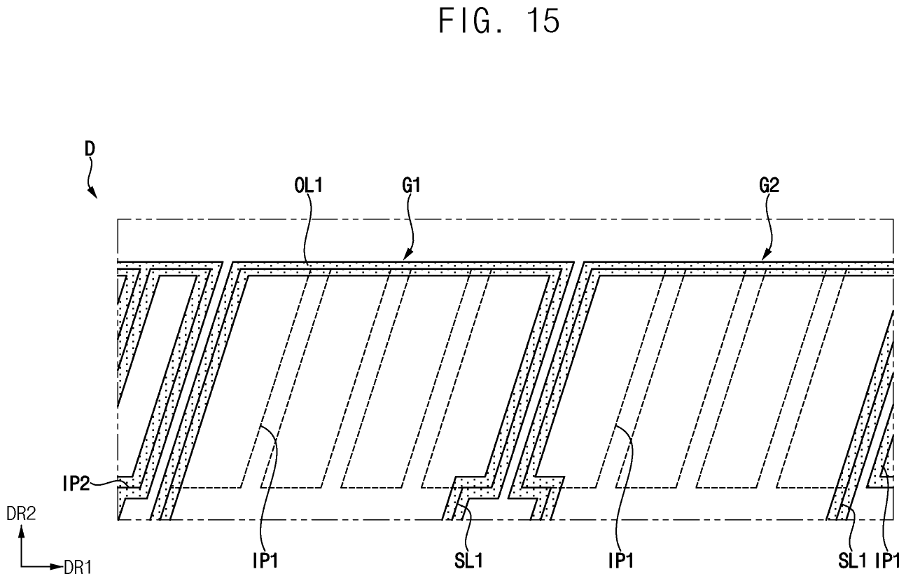

FIG. 14 is an enlarged plan view of another example of area B in FIG. 1. FIG. 15 is an enlarged plan view of area D of FIG. 14.

However, the display device DD described with reference to FIGS. 14 and 15 may be substantially the same or similar to the display device DD described with reference to FIGS. 8, 9, and 10 except for a part of the organic insulating layer OL. Hereinafter, descriptions overlapping with those of the display device DD described with reference to FIGS. 8, 9, 10, and 11 will be omitted or simplified.

Referring to FIGS. 14 and 15, the organic insulating layer OL may include a first organic insulating layer OL1 and a second organic insulating layer OL2, and the organic insulating layer OL may cover the edges of each of the first signal lines SL1, the edges of each of the second input pads IP2, a part of the second signal lines SL2, and a part of the third signal lines SL3.

The first signal lines SL1 and the first input pads IP1 may be grouped into a plurality of groups. In this case, each of the groups may include one first signal line SL1 and the plurality of first input pads IP1. In one or more embodiments, a part of the first organic insulating layer OL1 covering the edges of each of the first signal lines SL1 in a first group G1 among the groups may be disconnected from another part of the organic insulating layer OL, which covers the edges of each of the first signal lines SL1 in a second group G2 adjacent to the first group G1 among the groups. In addition, the part of the first organic insulating layer OL1 covering the edges of each of the first signal lines SL1 in the first group G1 may be disconnected from a part of the first organic insulating layer OL1 covering the edges of each of the second input pads IP2. Accordingly, the moisture permeation path through the organic insulating layer OL can be blocked more effectively.

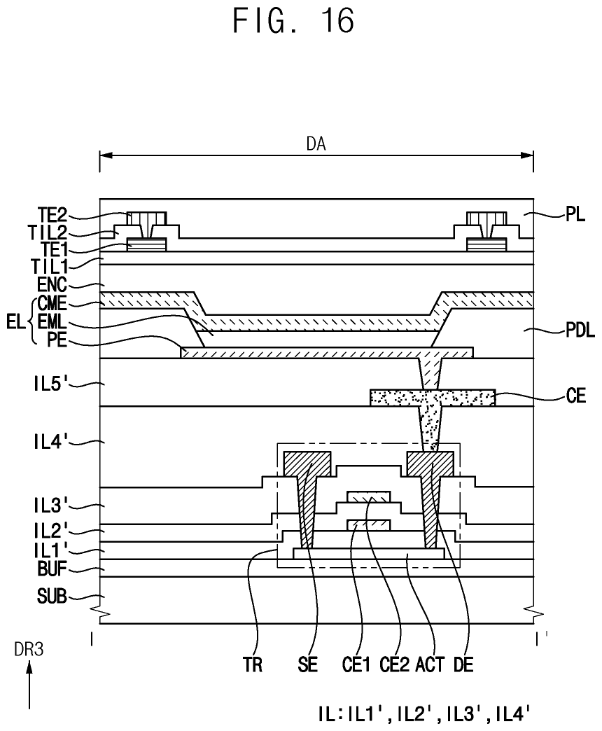

FIG. 16 is a cross-sectional view illustrating another example of a cross-section taken along the line I-I′ of FIG. 1. Hereinafter, descriptions overlapping with those of the display device DD described with reference to FIG. 4 will be omitted or simplified.

Referring to FIG. 16, the display device DD according to one or more embodiments of the present disclosure may include a substrate SUB, a buffer layer BUF, a transistor TR, an upper electrode CE2, first, second, third, fourth, and fifth insulating layers IL1′, IL2′, IL3′, IL4′, and IL5′, a connection electrode CE, a pixel-defining layer PDL, a light-emitting element EL, an encapsulation layer ENC, and a touch-sensing layer.

Here, the transistor TR may include an active pattern ACT, a lower electrode CE1, a source electrode SE, and a drain electrode DE. The light-emitting element EL may include a pixel electrode PE, a light-emitting layer EML, and a common electrode CME. The touch-sensing layer may include a first touch insulating layer TIL1, a second touch insulating layer TIL2, first touch electrodes TE1, second touch electrodes TE2, and a protective layer PL.

The active pattern ACT may be located on the buffer layer BUF. For example, the active pattern ACT may include an inorganic semiconductor, such as amorphous silicon or polycrystalline silicon. Alternatively, the active pattern ACT may include a metal oxide semiconductor.

The first insulating layer IL1′ covering the active pattern ACT may be located on the buffer layer BUF. For example, the first insulating layer IL1′ may include an inorganic material, such as silicon oxide (SiOₓ), silicon nitride (SiNₓ), silicon carbide (SiCₓ), silicon oxynitride (SiOₓN_{y}), and/or the like. These can be used alone or in combination with each other.

The lower electrode CE1 may be located on the first insulating layer IL1′. The lower electrode CE1 may overlap the channel area of the active pattern ACT. The lower electrode CE1 may include substantially the same material as the first gate electrode GE1 of FIG. 4.

The second insulating layer IL2′ covering the lower electrode CE1 may be located on the first insulating layer IL1′. For example, the second insulating layer IL2′ may include an inorganic material, such as silicon oxide (SiOₓ), silicon nitride (SiNₓ), silicon carbide (SiCₓ), silicon oxynitride (SiOₓN_{y}), and/or the like. These can be used alone or in combination with each other.

The upper electrode CE2 may be located on the second insulating layer IL2′. The upper electrode CE2 may overlap the lower electrode CE1. The upper electrode CE2 may include substantially the same material as the second gate electrode GE2 of FIG. 4.

The third insulating layer IL3′ covering the upper electrode CE2 may be located on the second insulating layer IL2′. For example, the third insulating layer IL3′ may include an inorganic material, such as silicon oxide (SiOₓ), silicon nitride (SiNₓ), silicon carbide (SiCₓ), silicon oxynitride (SiOₓN_{y}), and/or the like. These can be used alone or in combination with each other.

The source electrode SE and the drain electrode DE may be located on the third insulating layer IL3′. Each of the source electrode SE and the drain electrode DE may be connected to the active pattern ACT. The source electrode SE and the drain electrode DE may include substantially the same material as the first source electrode SE1 and the first drain electrode DE1 of FIG. 4.

The fourth insulating layer IL4′ may be located on the third insulating layer IL3′. The fourth insulating layer IL4′ may have a substantially flat upper surface. The fourth insulating layer IL4′ may include an organic material. That is, the fourth insulating layer IL4′ may include substantially the same material as the sixth insulating layer IL6 of FIG. 4.

The connection electrode CE may be located on the fourth insulating layer IL4′. The connection electrode CE may be connected to the source electrode SE or the drain electrode DE. The fifth insulating layer IL5′ covering the connection electrode CE may be located on the fourth insulating layer IL4′. The fifth insulating layer IL5′ may have a substantially flat top surface. The fifth insulating layer IL5′ may include an organic material. That is, the fifth insulating layer IL5′ may include substantially the same material as the seventh insulating layer IL7 of FIG. 4. In other words, the fifth insulating layer IL5′ may correspond to the organic insulating layer OL of FIGS. 8, 9, 10, 11, 12, 13, 14, and 15.

The first, second, third, and fourth insulating layers IL1′, IL2′, IL3′, and IL4′ may form one insulating structure IL. In this case, the insulating structure IL of FIG. 16 may correspond to the insulating structure IL of FIGS. 12 and 13. In addition, the insulating structure IL except for the first insulating layer IL1′ of FIG. 16 may correspond to the insulating structure IL′ of FIG. 12.

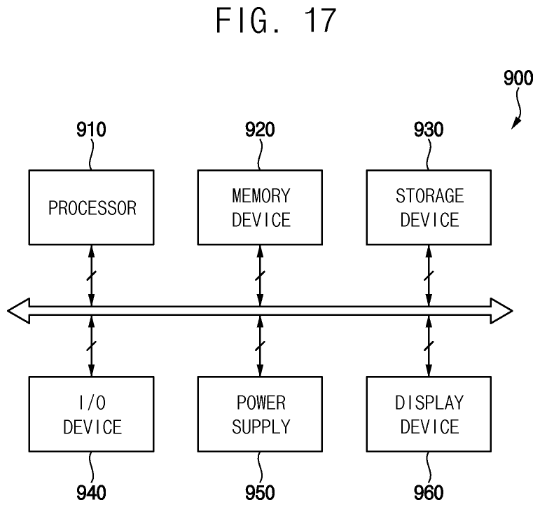

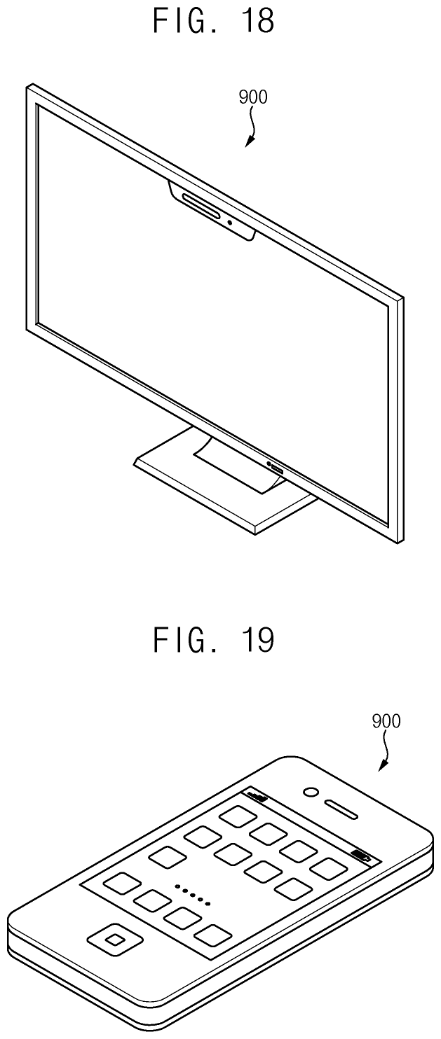

FIG. 17 is a block diagram illustrating an electronic device including the display device of FIG. 1. FIG. 18 is a view illustrating the electronic device of FIG. 17 implemented as a television. FIG. 19 is a view illustrating the electronic device of FIG. 17 implemented as a smartphone.

Referring to FIGS. 17, 18, and 19, in one or more embodiments, an electronic device 900 may include a processor 910, a memory device 920, a storage device 930, an input/output device 940, a power supply 950, and a display device 960. In this case, the display device 960 may correspond to the display device DD described with reference to FIGS. 1 to 15. The electronic device 900 may further include several ports capable of communicating with a video card, a sound card, a memory card, a USB device, and/or the like.

In one or more embodiments, as shown in FIG. 18, the electronic device 900 may be implemented as a television. In one or more other embodiments, as shown in FIG. 19, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and/or the like.

The processor 910 may perform certain calculations or tasks. In one or more embodiments, the processor 910 may be a microprocessor, a central processing unit (CPU), an application processor (AP), and/or the like. The processor 910 may be connected to other components through an address bus, a control bus, a data bus, and/or the like. The processor 910 may also be connected to an expansion bus, such as a peripheral component interconnect (PCI) bus.

The memory device 920 may store data suitable for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a non-volatile memory device, such as a ferroelectric random access memory (FRAM) device and/or a volatile memory device, such as a dynamic random access memory (DRAM) device, a static random access memory (SRAM) device, and a mobile DRAM device, and/or the like.

The storage device 930 may include a solid state drive (SSD), a hard disk drive (HDD), a CD-ROM, and/or the like.

The input/output device 940 may include input means, such as a keyboard, keypad, touch pad, touch screen, mouse, and/or the like, and output means, such as a speaker, a printer, and/or the like.

The power supply 950 may supply power suitable for the operation of the electronic device 900. The display device 960 may be connected to other components through buses or other communication links. In one or more embodiments, the display device 960 may be included in the input/output device 940.

The present disclosure can be applied to various display devices. For example, the present disclosure is applicable to various display devices, such as display devices for vehicles, ships and aircraft, portable communication devices, display devices for exhibition or information transmission, medical display devices, and/or the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, with functional equivalents thereof to be included therein.

What is claimed is:

1. A display device comprising:
a substrate comprising a display area, and a pad area at one side of the display area;
first input pads and second input pads at one side of the pad area above the substrate;
signal pads in the pad area above the substrate, and under the first and second input pads in a plan view;
first signal lines electrically connecting the signal pads and the first input pads in a one-to-many or many-to-many manner;
second signal lines electrically connecting the signal pads and the second input pads in a one-to-one manner; and
an organic insulating layer covering edges of the first signal lines so that at least a part of upper surfaces of the first signals lines is exposed.

2. The display device of claim 1, wherein the organic insulating layer extends to cover edges of the second input pads and at least a part of the second signal lines.

3. The display device of claim 2, wherein the organic insulating layer exposes a part of the second signal lines overlapping an area adjacent to the second input pads.

4. The display device of claim 1, further comprising:
a lighting circuit portion in the pad area above the substrate; and
third signal lines connected to the lighting circuit portion,
wherein the organic insulating layer extends to cover at least a part of the third signal lines, and exposes a part of the third signal lines overlapping an area adjacent to ends of the third signal lines.

5. The display device of claim 1, wherein at least a part of a space between corresponding ones of the first signal lines is exposed by the organic insulating layer.

6. The display device of claim 1, further comprising a dummy pad between corresponding ones of the first input pads in the pad area,
wherein the organic insulating layer extends to cover at least a part of edges of the dummy pad.

7. The display device of claim 6, wherein the organic insulating layer exposes another part of the edges of the dummy pad.

8. The display device of claim 1, wherein the first signal lines and the first input pads are grouped into groups, and
wherein a part of the organic insulating layer covering edges of the first signal lines in a first group among the groups is disconnected from another part of the organic insulating layer covering edges of the first signal lines in a second group among the groups that is adjacent to the first group.

9. The display device of claim 1, wherein the first input pads and the second input pads comprise:
a first conductive layer;
a second conductive layer above the first conductive layer; and
a third conductive layer above the second conductive layer.

10. The display device of claim 9, wherein the first signal lines are integral with the third conductive layer of the first input pads, and
wherein the second signal lines are integral with the third conductive layer of the second input pads.

11. The display device of claim 9, wherein the third conductive layer has a multilayer structure comprising Ti/Al/Ti.

12. The display device of claim 1, further comprising:
output pads at another side of the pad area above the substrate; and
a driving integrated circuit on the first input pads, the second input pads, and the output pads, and electrically connected to the first input pads, the second input pads, and the output pads.

13. A display device comprising:
a substrate comprising a display area, and a pad area at one side of the display area;
first input pads and second input pads at one side of the pad area above the substrate;
first signal lines electrically connected to the first input pads in a one-to-many correspondence;
second signal lines electrically connected to the second input pads in a one-to-one or many-to-one correspondence; and
an organic insulating layer covering edges of the first signal lines so that at least a part of an upper surface of each of the first signals lines is exposed.

14. The display device of claim 13, wherein the organic insulating layer extends to cover edges of each of the second input pads and at least a part of the second signal lines.

15. The display device of claim 13, wherein the organic insulating layer exposes a part of the second signal lines overlapping an area adjacent to the second input pads.

16. The display device of claim 13, further comprising:
a lighting circuit portion in the pad area above the substrate; and
third signal lines connected to the lighting circuit portion,
wherein the organic insulating layer extends to cover at least a part of the third signal lines, and exposes a part of the third signal lines overlapping an area adjacent to ends of the third signal lines.

17. The display device of claim 13, wherein at least a part of a space between corresponding ones of the first signal lines is exposed by the organic insulating layer.

18. The display device of claim 13, further comprising a dummy pad between corresponding ones of the first input pads in the pad area,
wherein the organic insulating layer extends to cover at least a part of edges of the dummy pad.

19. The display device of claim 18, wherein the organic insulating layer exposes another part of the edges of the dummy pad.

20. The display device of claim 13, wherein the first signal lines and the first input pads are grouped into groups, and
wherein a part of the organic insulating layer covering edges of the first signal lines in a first group among the groups is disconnected from another part of the organic insulating layer covering edges of the first signal lines in a second group among the groups that is adjacent to the first group.
